(19) United States
(12) Patent Application Publication
(10) Pub. No.: US 2026/0371657 A1
(43) Pub. Date: Nov. 19, 2026

(54) MICROELECTRONIC DEVICES, AND RELATED METHODS AND MEMORY DEVICES

(71) Applicant: Micron Technology, Inc., Boise, ID (US)

(72) Inventors: Pankaj Sharma, Boise, ID (US); Haitao Liu, Boise, ID (US); Naveen Kaushik, Boise, ID (US); Albert Fayrushin, Boise, ID (US); Sundaravadivel Rajarajan, San Jose, CA (US)

(21) Appl. No.: 19/659,719

(22) Filed: Apr. 27, 2026

Related U.S. Application Data
(60) Provisional application No. 63/808,358, filed on May 19, 2025.

(51) Int. Cl. H10D 30/69; H10B 43/27; H10B 43/35; H10D 30/01; H10D 62/10

(52) U.S. Cl. CPC H10D 30/696; H10B 43/27; H10B 43/35; H10D 30/0413; H10D 30/693; H10D 62/116

(57) ABSTRACT

A microelectronic device includes a stack structure, a cell pillar structure, a dielectric spacer structure, and a source structure. The stack structure includes tiers vertically stacked relative to one another and respectively including conductive material and insulative material vertically neighboring the conductive material. The cell pillar structure vertically extends through the stack structure and includes a fill material, a channel material outwardly horizontally surrounding the fill material, and an outer material stack outwardly horizontally surrounding the channel material. The dielectric spacer structure is vertically above the stack structure and in physical contact with an upper portion of an outer side surface of the channel material of the cell pillar structure. The source structure includes doped semiconductor material covering the dielectric spacer structure and physically contacting an upper portion of an inner side surface of the channel material of the cell pillar structure. Related methods and memory devices are also described.

### CROSS-REFERENCE TO RELATED APPLICATIONS

This application claims the benefit under 35 U.S.C. § 119(e) of U.S. Provisional Patent Application Ser. No. 63/808,358, filed May 19, 2025, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in one or more decks (e.g., stack structures) including tiers of conductive materials and insulative materials. Each vertical memory string may include at least one select device coupled in series to a serial combination of vertically stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Conventional memory device configurations can be complex and costly to manufacture, can impede reductions to the size (e.g., horizontal footprint) of a memory device, and/or can impede improvements in the performance (e.g., faster memory cell ON/OFF speed, lower threshold switching voltage requirements, faster data transfer rates, lower power consumption) of the memory device.

### BRIEF DESCRIPTION OF THE DRAWINGS

FIGS. 1A through 1J are simplified, partial vertical cross-sectional views of a microelectronic device structure at different processing stages of a method of forming a microelectronic device, in accordance with embodiments of the disclosure.

FIG. 2 is a schematic block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device, such as 3D NAND Flash memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe-and Ni-based alloy, a Co-and Ni-based alloy, an Fe-and Co-based alloy, a Co-and Ni-and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, a “semiconductor structure” or a “semiconductor structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

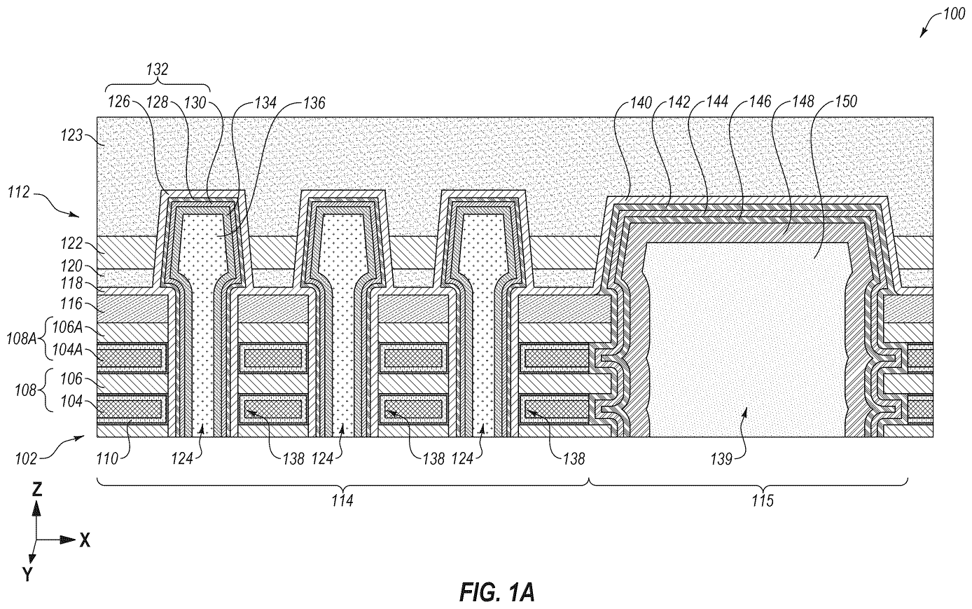

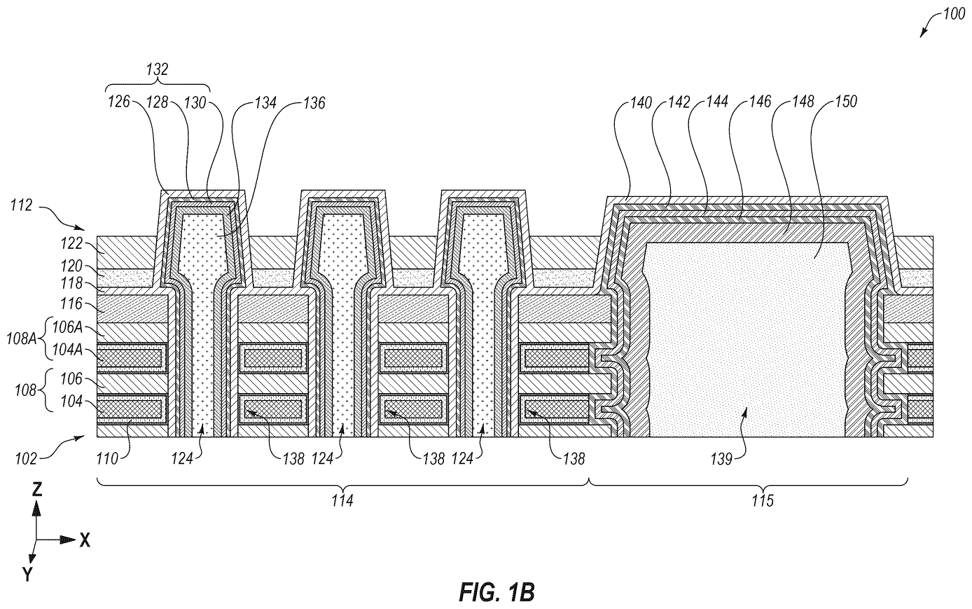

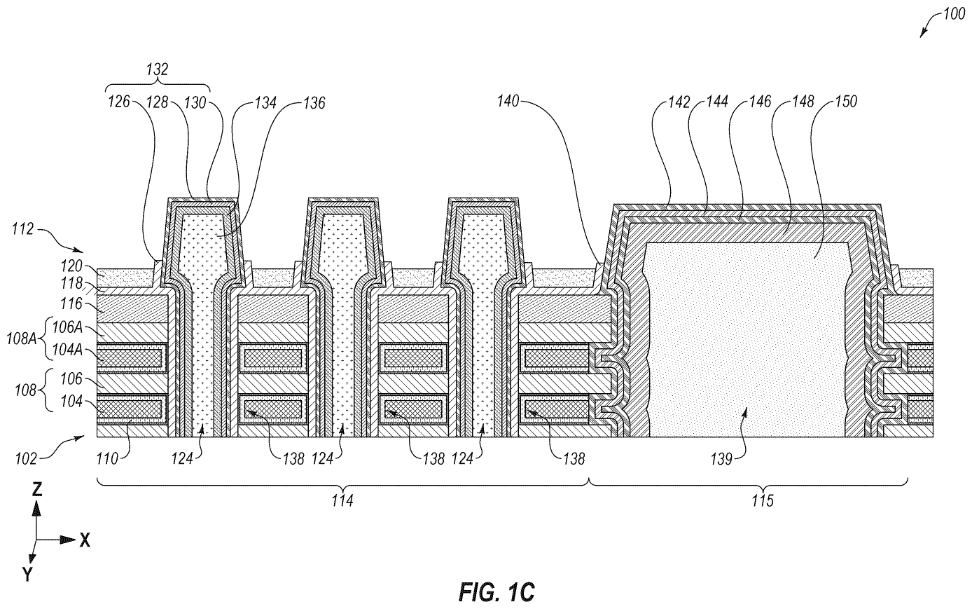

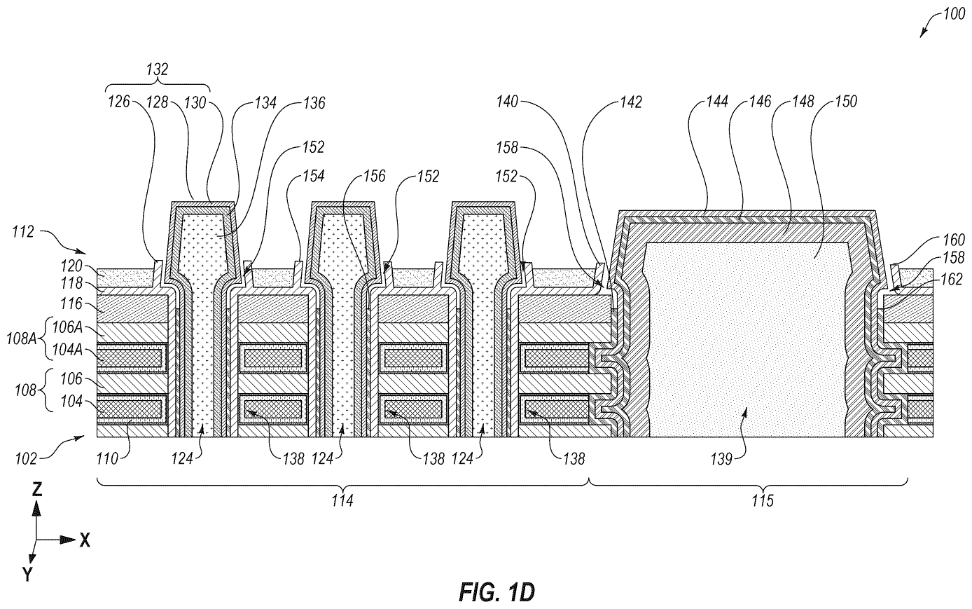

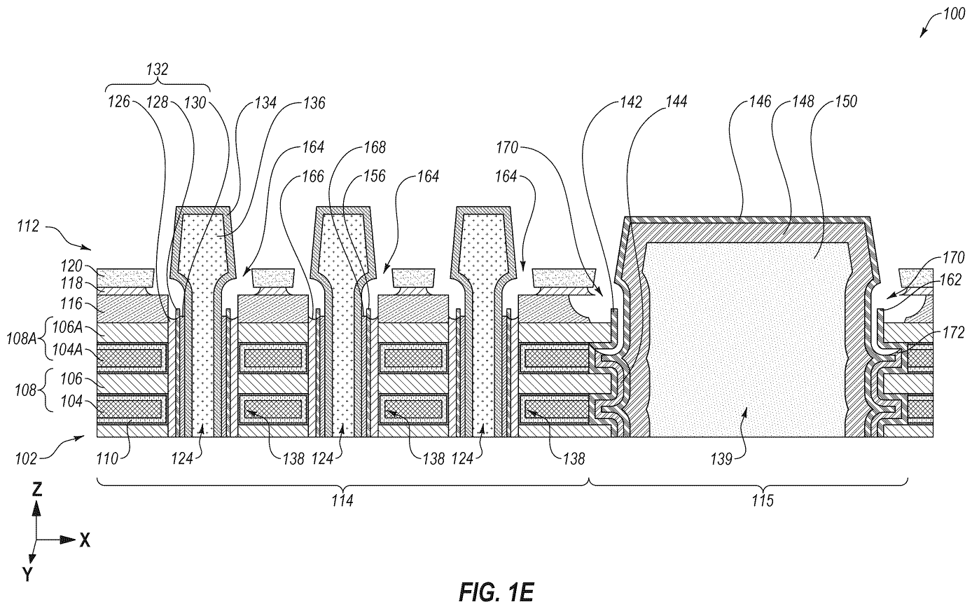

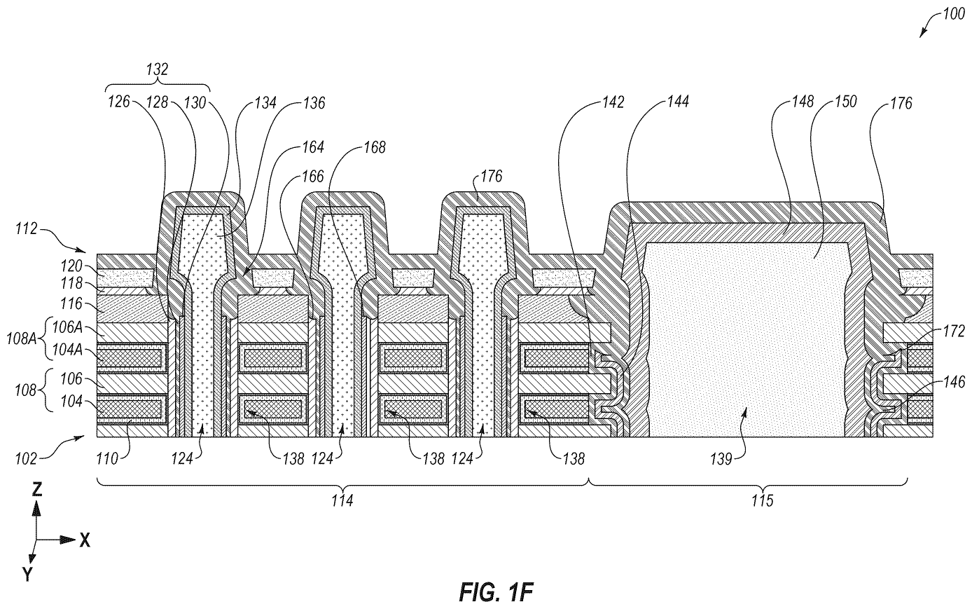

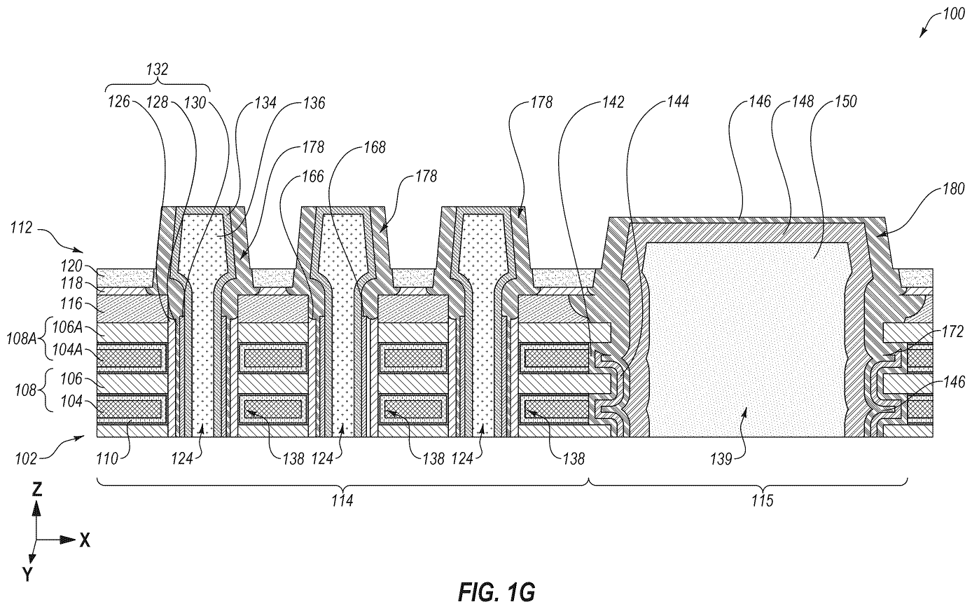

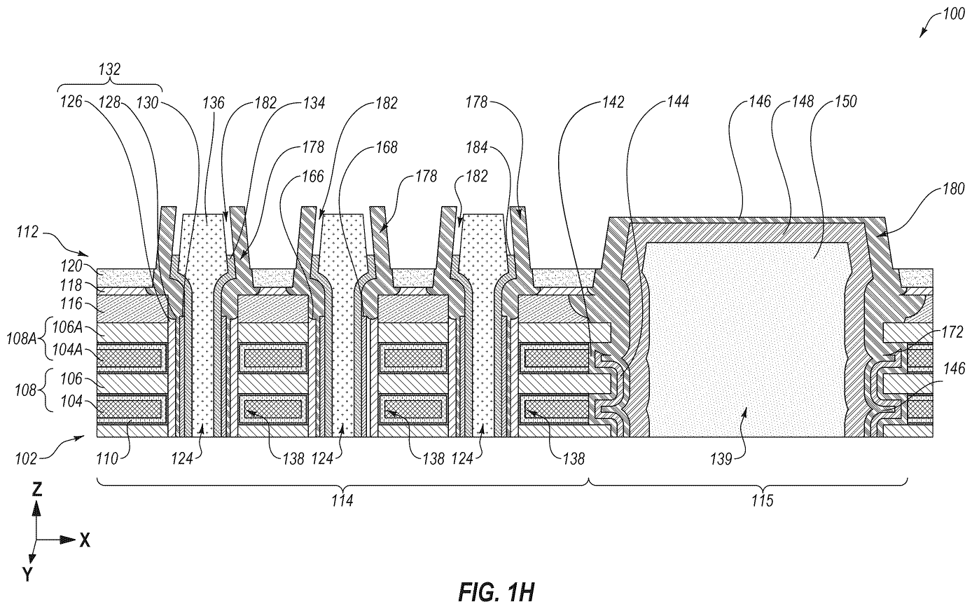

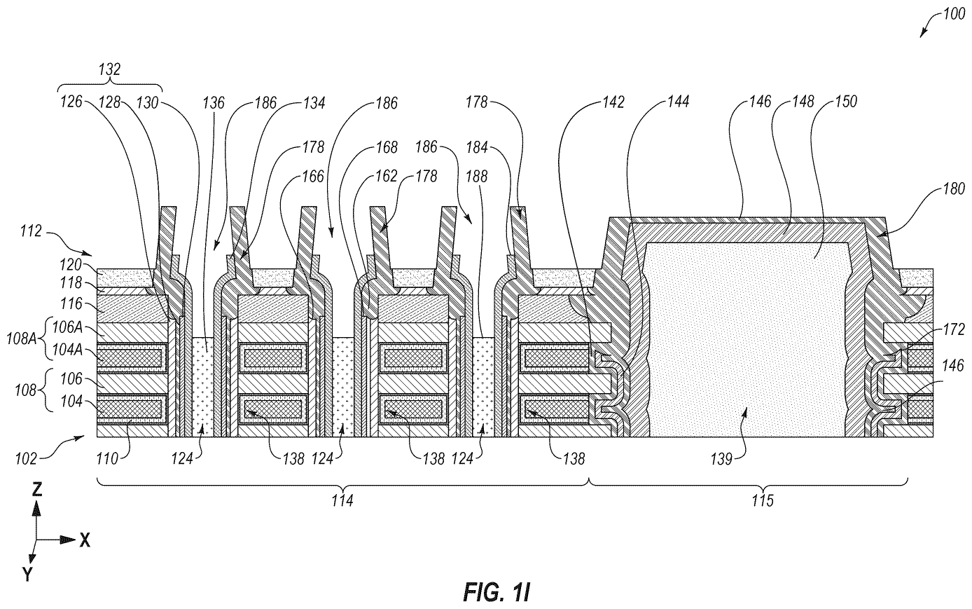

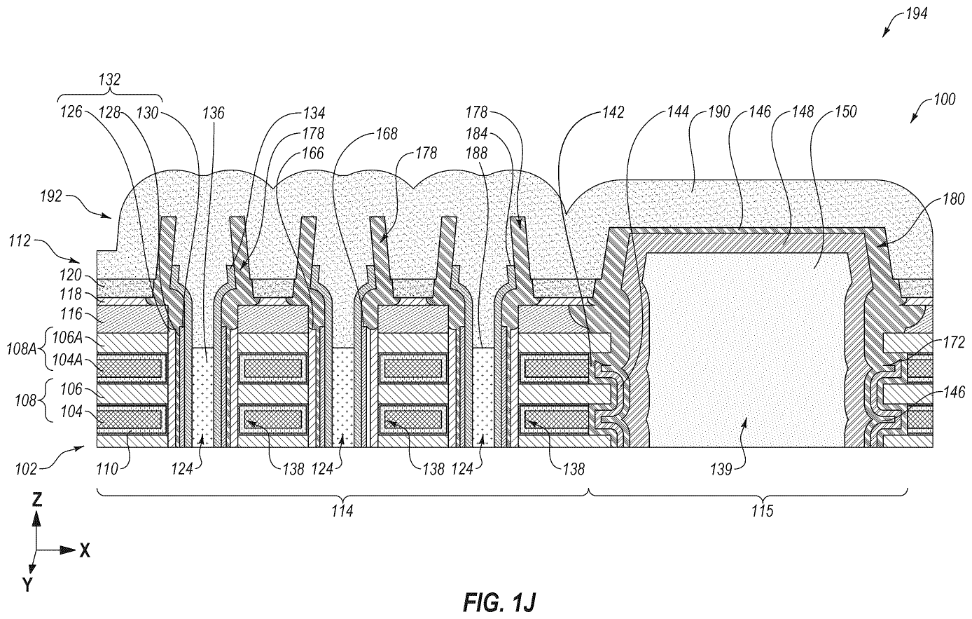

FIGS. 1A through 1J are simplified, partial vertical cross-sectional views illustrating a microelectronic device structure 100 at different processing stages of a method of forming a microelectronic device (e.g., a memory device, such as a 3D NAND Flash memory device), in accordance with embodiments of the disclosure. With the description provided below, it will be readily apparent to one of ordinary skill in the art that the methods and structures described herein may be used to form various devices and electronic systems.

Referring to FIG. 1A, a microelectronic device structure 100 may be formed to include a stack structure 102 having a vertically alternating (e.g., in the Z-direction) sequence of conductive material 104 and insulative material 106 and arranged in tiers 108. Each of the tiers 108 of the stack structure 102 may include a level of the conductive material 104 vertically neighboring a level of the insulative material 106. In some embodiments, the conductive material 104 is formed of and includes one or more of W, Mo, Ru, and Ti; and the insulative material 106 is formed of and includes SiOₓ (e.g., SiO₂). The stack structure 102 may be formed to include any desired number of the tiers 108. By way of non-limiting example, the stack structure 102 may be formed to include greater than or equal to sixteen (16) of the tiers 108, such as greater than or equal to thirty-two (32) of the tiers 108, greater than or equal to sixty-four (64) of the tiers 108, greater than or equal to one hundred and twenty-eight (128) of the tiers 108, greater than or equal to two hundred and fifty-six (256) of the tiers 108, greater than or equal to five hundred and twelve (512) of the tiers 108, or greater than or equal to one thousand and twenty-four (1024) of the tiers 108.

Optionally, at least one liner material 110 (e.g., insulative liner material(s), conductive liner material(s)) may be formed at least partially around the conductive material 104 of respective ones of the tiers 108 of the stack structure 102. The liner material 110 may, for example, be formed of and include one or more a metal (e.g., titanium, tantalum), an alloy, a metal nitride (e.g., tungsten nitride, titanium nitride, tantalum nitride), and a metal oxide (e.g., aluminum oxide). In some embodiments, the liner material 110 comprises at least one additional conductive material employed as a seed material for the formation of the conductive material 104. In some embodiments, the liner material 110 includes titanium nitride (TiN_{y}). In further embodiments, the liner material 110 further includes aluminum oxide (AlOₓ). As a non-limiting example, AlOₓ may be formed directly adjacent the insulative material 106 of respective ones of the tiers 108 of the stack structure 102, TiN_{y} may be formed directly adjacent the AlOₓ, and W may be formed directly adjacent the TiN_{y}.

The stack structure 102 has a source side and a drain side. The source side of the stack structure 102 may be considered to be a first vertical boundary (e.g., a first end) of the stack structure 102 most vertically proximate to a first tier 108A of the stack structure 102, and a drain side of the stack structure 102 may be considered to be a second vertical boundary (e.g., a second end) of the stack structure 102 most vertically distal from the first tier 108A of the stack structure 102. As described in further detail below, the first tier 108A (and, hence, the source side) of the stack structure 102 may later be vertically positioned proximate a source structure subsequently formed through the methods of the disclosure.

The first tier 108A of the stack structure 102 includes a first conductive material 104A and a first insulative material 106A vertically neighboring the first conductive material 104A. The first conductive material 104A may be employed for source-side gate-induced drain-leakage (GIDL) generation (GG) structures of the stack structure 102. The conductive material 104 of at least one other of the tiers 108 proximate the drain side of the stack structure 102 may be employed for drain-side GG structures of the stack structure 102. In addition, the conductive material 104 of one or more others of tiers 108 of the stack structure 102 relatively vertically proximate to the first tier 108A (and, hence, the source-side GG structures) may be employed as source-side select gate (SGS) structure(s) of the stack structure 102; and the conductive material 104 of one or more yet others of tiers 108 vertically proximate to proximate to the drain-side GG structures may be employed for drain-side select gate (SGD) structure(s) of the stack structure 102. Furthermore, the conductive material 104 of some further ones of the tiers 108 of the stack structure 102 may be employed for local word line (LWL) structures (e.g., local access line structures) of the stack structure 102.

Still referring to FIG. 1A, the microelectronic device structure 100 may further include an additional stack structure 112 on or over the stack structure 102. The additional stack structure 112 may include an isolation material 116 on or over the stack structure 102; optionally, an insulative liner material 118 on or over the isolation material 116; a capping material 120 on or over the insulative liner material 118 (if any, or the isolation material 116); an additional isolation material 122 on or over the capping material 120; and a semiconductor material 123 on or over the additional isolation material 122.

The isolation material 116 may be formed on or over the first tier 108A of the stack structure 102, such as on the first insulative material 106A of the first tier 108A of the stack structure 102. The isolation material 116 may be formed of and include at least one insulative material, such as a one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the isolation material 116 is formed of and includes a dielectric oxide material (e.g., SiOₓ, such as SiO₂) formed through a high aspect ratio process (HARP). Such a dielectric oxide material is also referred to herein as a HARP oxide. The HARP oxide may be formed by way of a thermal, non-plasma-based CVD process, or the HARP oxide may be formed by way of a PECVD process.

The insulative liner material 118, if any, may be formed on or over a surface (e.g., an upper surface) of the isolation material 116. The insulative liner material 118 may be formed of and include at least one additional dielectric material, such as a one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the insulative liner material 118 is formed of and includes dielectric oxide material, such as SiOₓ (e.g., SiO₂). In additional embodiments, the insulative liner material 118 is not formed (e.g., is absent from the additional stack structure 112).

If the isolation material 116 and the insulative liner material 118 (if any) are each formed of and include dielectric oxide material (e.g., SiOₓ, such as SiO₂), a density of the isolation material 116 may be different (e.g., less than) that of the insulative liner material 118. As a non-limiting example, a density of the isolation material 116 (e.g., HARP oxide) may be within a range of from about 1.9 grams per cubic centimeter (g/cm³) to about 2.1 g/cm³, and a density of the insulative liner material 118 (e.g., non-HARP oxide) may be greater than that of the isolation material 116, such as greater than or equal to about 2.2 g/cm³. The difference in the densities of the isolation material 116 and the insulative liner material 118 may affect an etch rate of the isolation material 116 relative to an etch rate the insulative liner material 118 during mutual exposure to an etchant. For example, the isolation material 116 may be etched at a relatively faster rate than the insulative liner material 118 during mutual exposure to an etchant, as described in further detail below with reference to FIG. 1E. In addition, discernable (e.g., observable) interfaces may be exhibited between the isolation material 116 and the insulative liner material 118, even if the isolation material 116 and the insulative liner material 118 have a same material composition as one another (e.g., SiOₓ, such as SiO₂) but are formed through different processes (e.g., HARP vs. non-HARP processes) than one another.

The capping material 120 (also referred to herein as an “etch stop material”) may be formed on or over a surface (e.g., an upper surface) of the insulative liner material 118 (if any, or a surface of the isolation material 116). The capping material 120 may comprise one or more of a semiconductor material, an insulative material, and a conductive material having etch selectivity relative to the isolation material 116, the insulative liner material 118 (if any), and the additional isolation material 122, as well as additional features of the microelectronic device structure (as described in further detail below). By way of non-limiting example, the capping material 120 may material formed of and includes semiconductor material, such as one or more of doped semiconductor material and substantially undoped (e.g., intrinsic) semiconductor material. In some embodiments, the capping material 120 is formed of and includes substantially undoped (e.g., intrinsic) polycrystalline silicon (also referred to herein as “polysilicon”). In additional embodiments, the capping material 120 is formed of and includes polycrystalline silicon doped (e.g., impregnated) with one or more conductivity enhancing species (e.g., one or more N-type dopants, one or more P-type dopants). For example, the capping material 120 may be formed of and include polycrystalline silicon doped with at least one N-type dopant (e.g., one or more of phosphorus, arsenic, antimony, and bismuth). As another example, the capping material 120 may be formed of and include polycrystalline silicon doped with at least one P-type dopant (e.g., one or more of boron, aluminum, and gallium).

The additional isolation material 122 may be formed on or over a surface (e.g., an upper surface) of the capping material 120. The additional isolation material 122 may be formed of and include insulative material, such as a one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the additional isolation material 122 is formed of and includes dielectric oxide material (e.g., SiOₓ, such as SiO₂) formed through a material deposition process (e.g., a CVD process, such as a PECVD process, or a thermal CVD process; an ALD process, such as a PEALD process) employing tetraethoxysilane (TEOS) as a precursor. Such a dielectric oxide material is also referred to herein as a TEOS oxide. In additional embodiments, the additional isolation material 122 is formed of and includes dielectric oxide material (e.g., SiOₓ, such as SiO₂) formed by way of a different process (e.g., a different ALD process, such a thermal ALD process; a different CVD process).

The semiconductor material 123 (also referred to herein as a “bulk semiconductor material”) may formed on or over a surface (e.g., an upper surface) of the additional isolation material 122. The semiconductor material 123 may be doped or may be substantially undoped. In some embodiments, the semiconductor material 123 is formed of and includes substantially undoped (e.g., intrinsic) polycrystalline silicon. In additional embodiments, the semiconductor material 123 is formed of and includes polycrystalline silicon doped with one or more conductivity enhancing species (e.g., one or more N-type dopants, one or more P-type dopants). For example, the semiconductor material 123 may be formed of and include polycrystalline silicon doped (e.g., relatively highly doped) with at least one N-type dopant (e.g., one or more of phosphorus, arsenic, antimony, and bismuth). As another example, the semiconductor material 123 may be formed of and include polycrystalline silicon doped with at least one P-type dopant (e.g., one or more of boron, aluminum, and gallium). A material composition of the semiconductor material 123 may be substantially the same as a material composition of the capping material 120, or the material composition of the semiconductor material 123 may be different than the material composition of the capping material 120.

Still referring to FIG. 1A, the microelectronic device structure 100 may include block regions 114 horizontally alternating (e.g., in the X-direction) with slot regions 115 (e.g., inter-block regions). An individual block region 114 may extend in a substantially linear path in the Y-direction. Two (2) of the block regions 114 horizontally neighboring one another in the X-direction may be horizontally separated from one another in the X-direction by a respective one of the slot regions 115. In addition, an individual slot region 115 may also extend in a substantially linear path in the Y-direction. Two (2) of the slot regions 115 horizontally neighboring one another in the X-direction may be horizontally separated from one another in the X-direction by a respective one of the block regions 114.

The block regions 114 of the microelectronic device structure 100 may respectively include cell pillar structures 124 within a horizontal area thereof. The cell pillar structures 124 may respectively vertically extend (e.g., in the Z-direction) through the stack structure 102 and into the additional stack structure 112. For example, the cell pillar structures 124 may respectively vertically extend completely through all of the tiers 108 of the stack structure 102; completely through each of the isolation material 116, the insulative liner material 118 (if any), the capping material 120, and the additional isolation material 122 of the additional stack structure 112; and into (e.g., only partially through) the semiconductor material 123 of the additional stack structure 112. First ends (e.g., source-side ends, first vertical boundaries, source-side vertical boundaries) of the cell pillar structures 124 may be vertically positioned within a vertical span of the semiconductor material 123 of the additional stack structure 112. Portions (e.g., upper portions) of the cell pillar structures 124 within a vertical extent (e.g., a vertical span) of the additional stack structure 112 may have relatively larger horizontal cross-sectional areas than additional portions (e.g., lower portions) of the cell pillar structures 124 within a vertical extent of the stack structure 102.

The cell pillar structures 124 may individually be formed of and include multiple (e.g., a plurality) materials facilitating the formation of vertically extending (e.g., in the Z-direction) strings of memory cells 138 within a respective block region 114. By way of non-limiting example, the cell pillar structures 124 may individually be formed to include an outer material stack 132, channel material 134 inwardly neighboring the outer material stack 132, and fill material 136 inwardly neighboring the channel material 134.

The outer material stack 132 of respective ones of the cell pillar structures 124 may include charge-blocking material 126, such as first dielectric oxide material (e.g., SiOₓ, such as SiO₂; AlOₓ, such as Al₂O₃); charge-trapping material 128, such as dielectric nitride material (e.g., SiN_{y}, such as Si₃N₄); and band-engineered (BE) dielectric material (also referred to herein as a “tunnel dielectric material), such as second dielectric oxide material (e.g., SiOₓ, such as SiO₂). The charge-blocking material 126 may be formed on or over (e.g., directly adjacent to) surfaces of the stack structure 102 and the additional stack structure 112. The charge-trapping material 128 may be formed on or over (e.g., directly adjacent to) inner surfaces of the charge-blocking material 126. The BE dielectric material 130 may be formed on or over (e.g., directly adjacent to) inner surfaces of the charge-trapping material 128. As shown in FIG. 1A, an outer side surface (e.g., an outer sidewall) and a first vertical end (e.g., an upper end) the BE dielectric material 130 may be outwardly surrounded by the charge-trapping material 128; and an outer side surface (e.g., an outer sidewall) and a first vertical end (e.g., an upper end) of the charge-trapping material 128 may be outwardly surrounded by the charge-blocking material 126. In some embodiments, the outer material stack 132 of respective ones of the cell pillar structures 124 comprises an oxide-nitride-oxide (ONO) stack.

The channel material 134 of respective ones of the cell pillar structures 124 may be formed of and include semiconductor material. In some embodiments, the channel material 134 is formed of and includes semiconductor material (e.g., polycrystalline silicon) doped with at least one P-type dopant (e.g., one or more of boron, aluminum, and gallium) or at least one N-type dopant (e.g., one or more of phosphorus, arsenic, antimony, and bismuth), at an atomic dopant concentration less than or equal to about 1.0e17 dopant atoms per cubic centimeter. In additional embodiments, the channel material 134 is formed of and includes semiconductor material (e.g., polycrystalline silicon) doped with at least one P-type dopant or at least one N-type dopant, at an atomic concentration greater than about 1.0e17 dopant atoms per cubic centimeter. In further embodiments, the channel material 134 comprises undoped (e.g., intrinsic) semiconductor material (e.g., undoped polycrystalline silicon). In still further embodiments the channel material 134 is formed of at least one oxide semiconductor material. The channel material 134 may be substantially homogeneous, or the channel material 134 may be heterogeneous. As shown in FIG. 1A, the channel material 134 of an individual cell pillar structure 124 may be formed on or over (e.g., directly adjacent to) inner surfaces of the BE dielectric material 130 of the outer material stack 132. For an individual cell pillar structure 124, an outer side surface (e.g., an outer sidewall) and a first vertical end (e.g., an upper end) of the channel material 134 thereof may be outwardly surrounded by the BE dielectric material 130 of the outer material stack 132 thereof.

A material composition of the channel material 134 of respective ones of the cell pillar structures 124 may be substantially the same as a material composition of the capping material 120 of the additional stack structure 112, or the material composition of the channel material 134 of respective ones of the cell pillar structures 124 may be different than the material composition of the capping material 120 of the additional stack structure 112. In some embodiments, the channel material 134 of respective ones of the cell pillar structure 124 has an etch selectivity substantially similar to that of the capping material 120 of the additional stack structure 112. The channel material 134 and the capping material 120 may exhibit substantially the same etch rate during mutual exposure to an etchant. In additional embodiments, the channel material 134 of respective ones of the cell pillar structure 124 is selectively etchable relative to the capping material 120 of the additional stack structure 112. The channel material 134 and the capping material 120 may exhibit different etching rates than one another during mutual exposure to an etchant.

The fill material 136 of respective ones of the cell pillar structures 124 may be formed of and include insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), and at least one dielectric carboxynitride material (e.g., SiOₓC_{z}N_{y}). In some embodiments, the fill material 136 is formed of and includes dielectric oxide material (e.g., SiOₓ, such as SiO₂). The fill material 136 may be substantially homogeneous, or the fill material 136 may be heterogeneous. As shown in FIG. 1A, the fill material 136 of an individual cell pillar structure 124 may be formed on or over (e.g., directly adjacent to) inner surfaces of the channel material 134. For an individual cell pillar structure 124, an outer side surface (e.g., an outer sidewall) and a first vertical end (e.g., an upper end) the fill material 136 thereof may be outwardly surrounded by the channel material 134 thereof.

Intersections of the cell pillar structures 124 and the conductive material 104 (and/or the liner material 110) of some of the tiers 108 (e.g., local word line tiers, local access line tiers) of the stack structure 102 may define vertically extending strings of memory cells 138 coupled in series with one another within a respective block region 114 of the microelectronic device structure 100. An individual vertically extending string of memory cells 138 may vertically extend across and be substantially confined within a vertical span a group of the tiers 108 of the stack structure 102. In some embodiments, the memory cells 138 comprise so-called “MONOS” (metal-oxide-nitride-oxide-semiconductor) memory cells. In additional embodiments, the memory cells 138 comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells 138 comprise so-called “floating gate” memory cells including floating gates (e.g., metallic floating gates) as charge storage structures. The floating gates may horizontally intervene between central structures of the cell pillar structures 124 and the conductive material 104 of some of the tiers 108 of the stack structure 102. An individual block region 114 of the microelectronic device structure 100 may include at least one array of the vertically extending strings of memory cells 138. In addition, intersections of the cell pillar structures 124 and the conductive material 104 (and/or the liner material 110) of some others of the tiers 108 (e.g., select gate tiers) of the stack structure 102 may define select transistors (e.g., SGD transistors, SGS transistors) coupled in series with the vertically extending strings of memory cells 138. In some embodiments, the select transistors comprise metal-oxide-semiconductor (MOS) transistors.

Still referring to FIG. 1A, the slot regions 115 of the microelectronic device structure 100 may respectively include a slot structure 139 within a horizontal area thereof. The slot structures 139 may respectively have a horizontally elongate shape (e.g., a generally rectangular horizontal cross-sectional shape), including a major horizontal dimension (e.g., length) oriented in the Y-direction, and minor horizontal dimension (e.g., width) oriented in the X-direction. In addition, the slot structures 139 may respectively vertically extend (e.g., in the Z-direction) through the stack structure 102 and into the additional stack structure 112. For example, the slot structures 139 may respectively vertically extend completely through all of the tiers 108 of the stack structure 102; completely through each of the isolation material 116, the insulative liner material 118 (if any), the capping material 120, and the additional isolation material 122 of the additional stack structure 112; and into (e.g., only partially through) the semiconductor material 123 of the additional stack structure 112. First ends (e.g., source-side ends, first vertical boundaries, source-side vertical boundaries) of the slot structures 139 may be vertically positioned within the vertical span of the semiconductor material 123 of the additional stack structure 112. As depicted in FIG. 1A, in some embodiments, a first end (e.g., an upper end) of an individual slot structure 139 within an individual slot region 115 of the microelectronic device structure 100 is located at a vertical position (e.g., a vertical elevation) of a first end (e.g., an upper end) of an individual cell pillar structure 124 within an individual block region 114 of the microelectronic device structure 100.

The slot structures 139 may individually be formed of and include multiple materials (e.g., multiple insulative materials) stacked relative to one another. By way of non-limiting example, the slot structures 139 may individually be formed to include a first dielectric liner material 140, a second dielectric liner material 142 inwardly neighboring the first dielectric liner material 140, a third dielectric liner material 144 inwardly neighboring the second dielectric liner material 142, a fourth dielectric liner material 146 inwardly neighboring the third dielectric liner material 144, a fifth dielectric liner material 148 inwardly neighboring the fourth dielectric liner material 146, and additional fill material 150 inwardly neighboring the fifth dielectric liner material 148. As described in further detail below, in some embodiments, an individual slot structure 139 comprises an oxide-nitride-oxide-nitride-oxide-fill (ONONOF) stack.

The first dielectric liner material 140 of an individual slot structure 139 may be formed on or over (e.g., directly adjacent to) surfaces of the additional stack structure 112. For example, as shown in FIG. 1A, the first dielectric liner material 140 may be formed on or over surfaces of the insulative liner material 118 (if any), the capping material 120, the additional isolation material 122, and the semiconductor material 123 of the additional stack structure 112. A vertical span of the first dielectric liner material 140 of the slot structure 139 may be less than a vertical span of the slot structure 139 itself. For example, the first dielectric liner material 140 may be confined within a vertical span of the additional stack structure 112, such that the first dielectric liner material 140 does not vertically extend into a vertical span of the stack structure 102. In some embodiments, the first dielectric liner material 140 is substantially vertically confined above the isolation material 116 of the additional stack structure 112.

The first dielectric liner material 140 of an individual slot structure 139 may be formed of and include insulative material. In some embodiments, the first dielectric liner material 140 is formed of and includes dielectric oxide material (e.g., SiOₓ, such as SiO₂). The first dielectric liner material 140 may be substantially homogeneous, or the first dielectric liner material 140 may be heterogeneous. The first dielectric liner material 140 may have an etch selectivity substantially similar to that of each of the insulative liner material 118 (if any) and the charge-blocking material 126 of the outer material stack 132 of respective ones of the cell pillar structures 124. The first dielectric liner material 140, the insulative liner material 118 (if any), and the charge-blocking material 126 may exhibit substantially the same etch rate during mutual exposure to an etchant. A material composition of the first dielectric liner material 140 may be substantially the same as a material composition of each of the insulative liner material 118 (if any) and the charge-blocking material 126, or the material composition of the first dielectric liner material 140 may be different than a material composition of one or more (e.g., each) of the insulative liner material 118 (if any) and the charge-blocking material 126. In some embodiments, the first dielectric liner material 140, the insulative liner material 118 (if any), and the charge-blocking material 126 have substantially the same material composition as one another. For example, the first dielectric liner material 140, the insulative liner material 118 (if any), and the charge-blocking material 126 may respectively be formed of and include SiO₂.

The second dielectric liner material 142 of an individual slot structure 139 may be formed on or over (e.g., directly adjacent to) inner surfaces of the first dielectric liner material 140 of the slot structure 139, as well as on or over surfaces of the stack structure 102 and the additional stack structure 112. For example, as shown in FIG. 1A, the second dielectric liner material 142 may be formed on or over surfaces of respective ones of the tiers 108 (including surfaces of the conductive material 104, the insulative material 106, and the liner material 110 (if any) thereof) of the stack structure 102; surfaces of the isolation material 116 of the additional stack structure 112; and inner surfaces of the first dielectric liner material 140. A vertical span of the second dielectric liner material 142 of the slot structure 139 may be greater than the vertical span of the first dielectric liner material 140 of the slot structure 139.

The second dielectric liner material 142 of an individual slot structure 139 may be formed of and include insulative material. In some embodiments, the second dielectric liner material 142 is formed of and includes dielectric nitride material (e.g., SiN_{y}, such as Si₃N₄). The second dielectric liner material 142 may be substantially homogeneous, or the second dielectric liner material 142 may be heterogeneous. The second dielectric liner material 142 may have an etch selectivity substantially similar to that of the charge-trapping material 128 of the outer material stack 132 of respective ones of the cell pillar structures 124. The second dielectric liner material 142 and the charge-trapping material 128 may exhibit substantially the same etch rate during mutual exposure to an etchant. A material composition of the second dielectric liner material 142 may be substantially the same as a material composition of the charge-trapping material 128, or the material composition of the second dielectric liner material 142 may be different than the material composition of one or more (e.g., each) of the charge-trapping material 128. In some embodiments, the second dielectric liner material 142 and the charge-trapping material 128 have substantially the same material composition as one another. For example, the second dielectric liner material 142 and the charge-trapping material 128 may respectively be formed of and include Si₃N₄.

The third dielectric liner material 144 of an individual slot structure 139 may be formed on or over (e.g., directly adjacent to) inner surfaces of the second dielectric liner material 142 of the slot structure 139. For an individual slot structure 139, an outer side surface (e.g., an outer sidewall) and a first vertical end (e.g., an upper end) of the third dielectric liner material 144 thereof may be outwardly surrounded by the second dielectric liner material 142 of the slot structure 139.

The third dielectric liner material 144 of an individual slot structure 139 may be formed of and include insulative material. In some embodiments, the third dielectric liner material 144 is formed of and includes dielectric oxide material (e.g., SiOₓ, such as SiO₂). The third dielectric liner material 144 may be substantially homogeneous, or the third dielectric liner material 144 may be heterogeneous. The third dielectric liner material 144 may have an etch selectivity substantially similar to that of the BE dielectric material 130 of the outer material stack 132 of respective ones of the cell pillar structures 124. The third dielectric liner material 144 and the BE dielectric material 130 may exhibit substantially the same etch rate during mutual exposure to an etchant. A material composition of the third dielectric liner material 144 may be substantially the same as a material composition of the BE dielectric material 130, or the material composition of the third dielectric liner material 144 may be different than a material composition of the BE dielectric material 130. In some embodiments, the third dielectric liner material 144 and the BE dielectric material 130 have substantially the same material composition as one another. For example, the third dielectric liner material 144 and the BE dielectric material 130 may respectively be formed of and include SiO₂.

The fourth dielectric liner material 146 of an individual slot structure 139 may be formed on or over (e.g., directly adjacent to) inner surfaces of the third dielectric liner material 144 of the slot structure 139. For an individual slot structure 139, an outer side surface (e.g., an outer sidewall) and a first vertical end (e.g., an upper end) of the fourth dielectric liner material 146 thereof may be outwardly surrounded by the third dielectric liner material 144 of the slot structure 139.

The fourth dielectric liner material 146 of an individual slot structure 139 may be formed of and include insulative material. In some embodiments, the fourth dielectric liner material 146 is formed of and includes dielectric nitride material (e.g., SiN_{y}, such as Si₃N₄). The fourth dielectric liner material 146 may be substantially homogeneous, or the fourth dielectric liner material 146 may be heterogeneous. The fourth dielectric liner material 146 may have an etch selectivity substantially similar to that of each of the second dielectric liner material 142 of the slot structure 139 and the charge-trapping material 128 of the outer material stack 132 of respective ones of the cell pillar structures 124. A material composition of the fourth dielectric liner material 146 may be substantially the same as a material composition of each of the second dielectric liner material 142 and the charge-trapping material 128, or the material composition of the fourth dielectric liner material 146 may be different than a material composition of one or more (e.g., each) of the second dielectric liner material 142 and the charge-trapping material 128. In some embodiments, the fourth dielectric liner material 146, the second dielectric liner material 142, and the charge-trapping material 128 have substantially the same material composition as one another. For example, the fourth dielectric liner material 146, the second dielectric liner material 142, and the charge-trapping material 128 may respectively be formed of and include Si₃N₄.

The fifth dielectric liner material 148 of an individual slot structure 139 may be formed on or over (e.g., directly adjacent to) inner surfaces of the fourth dielectric liner material 146 of the slot structure 139. For an individual slot structure 139, an outer side surface (e.g., an outer sidewall) and a first vertical end (e.g., an upper end) of the fifth dielectric liner material 148 thereof may be outwardly surrounded by the fourth dielectric liner material 146 of the slot structure 139.

The fifth dielectric liner material 148 of an individual slot structure 139 may be formed of and include insulative material. In some embodiments, the fifth dielectric liner material 148 is formed of and includes dielectric oxide material (e.g., SiOₓ, such as SiO₂). The fifth dielectric liner material 148 may be substantially homogeneous, or the fifth dielectric liner material 148 may be heterogeneous. A material composition of the fifth dielectric liner material 148 may be substantially the same as a material composition each of the first dielectric liner material 140 and the third dielectric liner material 144 of the slot structure 139, and a material composition of each of the charge-blocking material 126 and the BE dielectric material 130 of the outer material stack 132 of respective ones of the cell pillar structures 124; or the material composition of the fifth dielectric liner material 148 may be different than a material composition of one or more (e.g., each) of the first dielectric liner material, the third dielectric liner material 144, the charge-blocking material 126, and the BE dielectric material 130. In some embodiments, the fifth dielectric liner material 148, the third dielectric liner material 144, the charge-blocking material 126, and the BE dielectric material 130 have substantially the same material composition as one another. For example, the fifth dielectric liner material 148, the third dielectric liner material 144, the charge-blocking material 126, and the BE dielectric material 130 may respectively be formed of and include SiO₂.

The additional fill material 150 of an individual slot structure 139 may be formed on or over (e.g., directly adjacent to) inner surfaces of the fifth dielectric liner material 148 of the slot structure 139. For an individual slot structure 139, an outer side surface (e.g., an outer sidewall) and a first vertical end (e.g., an upper end) of the additional fill material 150 thereof may be outwardly surrounded by the fifth dielectric liner material 148 of the slot structure 139.

The additional fill material 150 of an individual slot structure 139 may be formed of and include one or more of insulative material, semiconductor material, and conductive material. In some embodiments, the additional fill material 150 is formed of and includes insulative material, such as dielectric oxide material (e.g., SiOₓ, such as SiO₂). In additional embodiments, the additional fill material 150 is formed of and includes semiconductor material, such as polycrystalline silicon. The additional fill material 150 may be substantially homogeneous, or the additional fill material 150 may be heterogeneous.

Before proceeding to the discussion of FIGS. 1B through 1J, it will be understood that subsequent description of previously introduced feature(s) (e.g., region(s), material(s), structure(s), device(s)) —whether provided with reference to a subsequent figure or to the same figure following processing already described with respect to that figure —refers to remaining portion(s) or resulting portion(s) of the same feature(s) following completion of one or more processing act(s) previously described with respect to one or more preceding figures and/or the same figure, unless otherwise specified.

Referring next to FIG. 1B, illustrated is simplified, partial vertical cross-sectional view of the microelectronic device structure 100 at a processing stage of the method of forming a microelectronic device following the processing stage previously described with reference to FIG. 1A. As shown in FIG. 1B, the semiconductor material 123 (FIG. 1A) of the additional stack structure 112 may be selectively removed (e.g., selectively etched away, such as selectively wet etched away) through a first material removal process to expose (e.g., uncover) portions of the additional isolation material 122, the charge-blocking material 126 of the outer material stack 132 of respective ones of the cell pillar structures 124, and the first dielectric liner material 140 of respective ones of the slot structures 139. This first material removal process may substantially remove the semiconductor material 123 (FIG. 1A) without substantially removing the additional isolation material 122, the charge-blocking material 126 of the respective ones of the cell pillar structures 124, and the first dielectric liner material 140 of the respective ones of the slot structures 139. In some embodiments, the first material removal process is a wet etching process employing tetra-methyl ammonium hydroxide (TMAH) as an etchant. Following the first material removal process, the exposed portions of the charge-blocking material 126 of the respective ones of the cell pillar structures 124 and the exposed portions of the first dielectric liner material 140 of the respective ones of the slot structures 139 may vertically overlie (e.g., in the Z-direction) the additional isolation material 122.

Referring next to FIG. 1C, illustrated is simplified, partial vertical cross-sectional view of the microelectronic device structure 100 at a processing stage of the method of forming a microelectronic device following the processing stage previously described with reference to FIG. 1B. As shown in FIG. 1C, the additional isolation material 122 (FIG. 1B), portions (e.g., upper portions) of the charge-blocking material 126 of the outer material stack 132 of respective ones of the cell pillar structures 124 vertically above the capping material 120, and portions (e.g., upper portions) of the first dielectric liner material 140 of the respective ones of the slot structures 139 vertically above the capping material 120 may be selectively removed (e.g., selectively etched away, such as selectively wet etched away) through a second material removal process. The second material removal process may expose (e.g., uncover) portions of the capping material 120, portions of the charge-trapping material 128 of the outer material stack 132 of the respective ones of the cell pillar structures 124, and portions of the second dielectric liner material 142 of the respective ones of the slot structures 139. The second material removal process may substantially remove the additional isolation material 122 (FIG. 1B) and the portions (e.g., upper portions) of the charge-blocking material 126 and the first dielectric liner material 140 without substantially removing the capping material 120, the charge-trapping material 128 of the respective ones of the cell pillar structures 124, and the second dielectric liner material 142 of the respective ones of the slot structures 139. In some embodiments, the second material removal process is a wet etching process employing one or more of buffered oxide etchant (BOE) and dilute hydrofluoric acid (DHF) etchant. Following the second material removal process, the exposed portions of the charge-trapping material 128 of the respective ones of the cell pillar structures 124 and the exposed portions of the second dielectric liner material 142 of the respective ones of the slot structures 139 may vertically overlie (e.g., in the Z-direction) the capping material 120.

Referring next to FIG. 1D, illustrated is simplified, partial vertical cross-sectional view of the microelectronic device structure 100 at a processing stage of the method of forming a microelectronic device following the processing stage previously described with reference to FIG. 1C. As shown in FIG. 1D, portions (e.g., upper portions) of the charge-trapping material 128 of the outer material stack 132 of respective ones of the cell pillar structures 124, and portions (e.g., upper portions) of the second dielectric liner material 142 of respective ones of the slot structures 139 may be selectively removed (e.g., selectively etched away, such as selectively wet etched away) through a third material removal process. The third material removal process may expose (e.g., uncover) portions of the BE dielectric material 130 of the outer material stack 132 of the respective ones of the cell pillar structures 124, portions of the third dielectric liner material 144 of the respective ones of the slot structures 139, and portions of the isolation material 116. The third material removal process may remove the portions (e.g., upper portions) of the charge-trapping material 128 and the second dielectric liner material 142 without substantially removing the charge-blocking material 126 of the respective ones of the cell pillar structures 124, the BE dielectric material 130 of the respective ones of the cell pillar structures 124, the first dielectric liner material 140 of the respective ones of the slot structures 139, the third dielectric liner material 144 of the respective ones of the slot structures 139, the capping material 120, the insulative liner material 118 (if any), and the isolation material 116. In some embodiments, the third material removal process is a wet etching process employing hot phosphoric acid (H₃PO₄), such as H₃PO₄ at a temperature within a range of from about 150 °C to about 180 °C. Following the third material removal process, the exposed portions of the BE dielectric material 130 of the respective ones of the cell pillar structures 124 and the exposed portions of the third dielectric liner material 144 of the respective ones of the slot structures 139 may vertically overlie (e.g., in the Z-direction) the stack structure 102.

The third material removal process may form first recesses 152 respectively horizontally interposed between the BE dielectric material 130 and the charge-blocking material 126 of the outer material stack 132 of respective ones of the cell pillar structures 124. An individual first recess 152 associated with (e.g., within a horizontal area of) an individual cell pillar structure 124 may have an inner horizontal boundary defined by an outer side surface (e.g., an outer sidewall) of the BE dielectric material 130 of the cell pillar structure 124; an outer horizontal boundary defined by an inner side surface (e.g., an inner sidewall) of the charge-blocking material 126 of the cell pillar structure 124; an upper boundary (e.g., an upper end, a top) defined by an upper surface 154 of the charge-blocking material 126 of the cell pillar structure 124; and a lower boundary (e.g., a lower end, a bottom) defined by an upper surface 156 of the charge-trapping material 128 of the cell pillar structure 124. The lower boundary of an individual first recess 152 (and, hence, the upper surface 156 of the charge-trapping material 128) may be located at or below an upper boundary (e.g., an upper surface) of the isolation material 116. In some embodiments, the lower boundary of an individual first recess 152 is within a vertical span of the isolation material 116 of the additional stack structure 112.

The third material removal process may also form second recesses 158 respectively horizontally interposed between the third dielectric liner material 144 of respective ones of the slot structures 139 and each of the isolation material 116 and the first dielectric liner material 140 of the respective ones of the slot structures 139. An individual second recess 158 associated with an individual slot structure 139 may have an inner horizontal boundary defined by an outer side surface (e.g., an outer sidewall) of the third dielectric liner material 144 of the slot structure 139; an outer horizontal boundary defined by surfaces (e.g., a side surface and an upper surface) of the isolation material 116 and inner side surfaces (e.g., inner sidewalls) of the first dielectric liner material 140 of the slot structure 139; an upper boundary (e.g., an upper end, a top) defined by an upper surface 160 of the first dielectric liner material 140 of the slot structure 139; and a lower boundary (e.g., a lower end, a bottom) defined by an upper surface 162 of the second dielectric liner material 142 of the slot structure 139. The lower boundary of an individual second recess 158 may be located at or below an upper boundary (e.g., an upper surface) of the isolation material 116. In some embodiments, the lower boundary of an individual second recess 158 is within a vertical span of the isolation material 116 of the additional stack structure 112.

Referring next to FIG. 1E, illustrated is simplified, partial vertical cross-sectional view of the microelectronic device structure 100 at a processing stage of the method of forming a microelectronic device following the processing stage previously described with reference to FIG. 1D. As shown in FIG. 1E, portions (e.g., upper portions) of the charge-blocking material 126 and the BE dielectric material 130 of the outer material stack 132 of respective ones of the cell pillar structures 124, portions (e.g., upper portions) of the first dielectric liner material 140 (FIG. 1D) and the third dielectric liner material 144 of respective ones of the slot structures 139, and portions of the isolation material 116 and the insulative liner material 118 (if any) of the additional stack structure 112 may be selectively removed (e.g., selectively etched away, such as selectively wet etched away) through a fourth material removal process. The fourth material removal process may expose (e.g., uncover) portions of the channel material 134 of respective ones of the cell pillar structures 124, portions of the fourth dielectric liner material 146 of the respective ones of the slot structures 139, and portions of the first insulative material 106A of the first tier 108A of the stack structure 102. The fourth material removal process may remove the portions of the charge-blocking material 126 and the BE dielectric material 130 of the outer material stack 132 of respective ones of the cell pillar structures 124, the portions of the first dielectric liner material 140 (FIG. 1D) and the third dielectric liner material 144 of the respective ones of the slot structures 139, and the portions of the isolation material 116 and the insulative liner material 118 (if any) of the additional stack structure 112 without substantially removing the channel material 134 of respective ones of the cell pillar structures 124, the charge-trapping material 128 of the respective ones of the cell pillar structures 124, the second dielectric liner material 142 of the respective ones of the slot structures 139, the fourth dielectric liner material 146 of the respective ones of the slot structures 139, the capping material 120, and the isolation material 116. The fourth material removal process may also at least partially (e.g., substantially) maintain the first insulative material 106A of the first tier 108A of the stack structure 102. In some embodiments, the fourth material removal process is a wet etching process employing one or more of BOE and DHF etchant. Following the fourth material removal process, the exposed portions of the channel material 134 may vertically overlie (e.g., in the Z-direction) the stack structure 102. In addition, following the fourth material removal process, the exposed portions of the fourth dielectric liner material 146 of the respective ones of the slot structures 139 may vertically overlie (e.g., in the Z-direction) a lower boundary of the first conductive material 104A of the first tier 108A of the stack structure 102.

The fourth material removal process may expand (e.g., horizontally expand, vertically expand) the first recesses 152 (FIG. 1D) to form first additional recesses 164. The first additional recesses 164 may respectively be horizontally interposed between the channel material 134 of respective ones of the cell pillar structures 124 and each of the capping material 120, the insulative liner material 118 (if any), and the isolation material 116 of the additional stack structure 112. An individual first additional recess 164 associated with (e.g., within a horizontal area of) an individual cell pillar structure 124 may have an inner horizontal boundary defined by an outer side surface (e.g., an outer sidewall) of the channel material 134 of the cell pillar structure 124; an outer horizontal boundary defined by surfaces of the capping material 120, the insulative liner material 118 (if any), and the isolation material 116 of the additional stack structure 112; an upper boundary (e.g., an upper end, a top) defined by an upper surface of the capping material 120 of the additional stack structure 112; and a lower boundary (e.g., a lower end, a bottom) defined by each of an upper surface 166 of the charge-blocking material 126, the upper surface 156 of the charge-trapping material 128, and an upper surface 168 of the BE dielectric material 130 of the cell pillar structure 124. The lower boundary of an individual first additional recess 164 may have a non-planar shape complementary to a non-planar topography defined by exposed portions of the charge-blocking material 126, the charge-trapping material 128, and the BE dielectric material 130 of the cell pillar structure 124. The lower boundary of an individual first additional recess 164 may be located at or below an upper boundary (e.g., an upper surface) of the isolation material 116. In some embodiments, the lower boundary of an individual first additional recess 164 is within a vertical span of the isolation material 116 of the additional stack structure 112.

The fourth material removal process may also expand (e.g., horizontally expand, vertically expand) the second recesses 158 (FIG. 1D) to form second additional recesses 170. The second additional recesses 170 may respectively including an upper portion within a vertical span of the additional stack structure 112, and a lower portion continuous with the upper portion and at least partially within vertical span of the stack structure 102 (e.g., within a vertical span of the first tier 108A of the stack structure 102). The upper portion of an individual second additional recess 170 associated with an individual slot structure 139 may be horizontally interposed between the fourth dielectric liner material 146 of the slot structure 139 and each of the capping material 120, the insulative liner material 118 (if any), and the isolation material 116 of the additional stack structure 112. The lower portion of the second additional recess 170 may be horizontally interposed between the fourth dielectric liner material 146 and the second dielectric liner material 142 of the slot structure 139. An individual second additional recess 170 associated with an individual slot structure 139 may have an inner horizontal boundary defined by an outer side surface (e.g., an outer sidewall) of the fourth dielectric liner material 146 of the slot structure 139; an outer horizontal boundary defined by surfaces of the capping material 120, the insulative liner material 118 (if any), and the isolation material 116 of the additional stack structure 112, as well as surfaces of the second dielectric liner material 142 of the slot structure 139; an upper boundary (e.g., an upper end, a top) defined by an upper surface of the capping material 120 of the additional stack structure 112; and a lower boundary (e.g., a lower end, a bottom) defined by an upper surface 172 of the third dielectric liner material 144 of the slot structure 139. The lower boundary of an individual second additional recess 170 may be located at or below an upper boundary (e.g., an upper surface) of the first insulative material 106A of the first tier 108A of the stack structure 102. In some embodiments, the lower boundary of an individual second additional recess 170 is within a vertical span of the first conductive material 104A of the first tier 108A of the stack structure 102.

Referring next to FIG. 1F, illustrated is simplified, partial vertical cross-sectional view of the microelectronic device structure 100 at a processing stage of the method of forming a microelectronic device following the processing stage previously described with reference to FIG. 1E. As shown in FIG. 1F, a dielectric spacer material 176 may be formed (e.g., deposited, such as conformally deposited) on or over exposed surfaces of the cell pillar structures 124, the slot structures 139, the additional stack structure 112, and the stack structure 102. The dielectric spacer material 176 may substantially continuously extend across the block regions 114 and the slot regions 115 of the microelectronic device structure 100. The dielectric spacer material 176 may at least partially (e.g., substantially) conform to a topography defined by the surfaces upon which the dielectric spacer material 176 is formed. The dielectric spacer material 176 may substantially fill the first additional recesses 164 (FIG. 1E) and the second additional recesses 170 (FIG. 1E). The dielectric spacer material 176 may physically contact and substantially cover portions of the microelectronic device structure 100 exposed through the fourth material removal process previously described with reference to FIG. 1E, such as upper portions of the channel material 134 of the respective ones of the cell pillar structures 124, upper portions of the fourth dielectric liner material 146 of the respective ones of the slot structures 139, and portions of the additional stack structure 112 and the stack structure 102.

The dielectric spacer material 176 may be formed of and include insulative material. In some embodiments, the dielectric spacer material 176 is formed of and includes dielectric nitride material (e.g., SiN_{y}, such as Si₃N₄). The dielectric spacer material 176 may be substantially homogeneous, or the dielectric spacer material 176 may be heterogeneous. The dielectric spacer material 176 may have an etch selectivity substantially similar to that of each of the second dielectric liner material 142 of respective ones of the slot structures 139, the fourth dielectric liner material 146 of respective ones of the slot structures 139, and the charge-trapping material 128 of the outer material stack 132 of respective ones of the cell pillar structures 124. A material composition of the dielectric spacer material 176 may be substantially the same as a material composition of each of the second dielectric liner material 142, fourth dielectric liner material 146, and the charge-trapping material 128, or the material composition of the dielectric spacer material 176 may be different than a material composition of one or more (e.g., each) of the second dielectric liner material 142, the fourth dielectric liner material 146, and the charge-trapping material 128. In some embodiments, the dielectric spacer material 176 has substantially the same material composition as each of the second dielectric liner material 142, fourth dielectric liner material 146, and the charge-trapping material 128. For example, the dielectric spacer material 176, the second dielectric liner material 142, the fourth dielectric liner material 146, and the charge-trapping material 128 may respectively be formed of and include Si₃N₄.

Referring next to FIG. 1G, illustrated is simplified, partial vertical cross-sectional view of the microelectronic device structure 100 at a processing stage of the method of forming a microelectronic device following the processing stage previously described with reference to FIG. 1F. As shown in FIG. 1G, portions of the dielectric spacer material 176 (FIG. 1F) may be removed (e.g., punched through; etched away, such as dry etched away) by way of a fifth material process to form first spacer structures 178 within the block regions 114 and second spacer structures 180 within the slot regions 115. The fifth material removal process may remove portions of the dielectric spacer material 176 (FIG. 1F) on upper surfaces of the channel material 134 of respective ones of the cell pillar structures 124, additional portions of the dielectric spacer material 176 (FIG. 1F) on upper surfaces of the fourth dielectric liner material 146 of respective ones of the slot structures 139, and further portions of the dielectric spacer material 176 (FIG. 1F) on an upper surface of the capping material 120 of the additional stack structure 112. In some embodiments, the fifth material removal process is a dry etching process such as reactive ion etching (RIE) or inductively coupled plasma (ICP) etching. The first spacer structures 178 may be located within horizontal areas of the block regions 114 of the microelectronic device structure 100, and may comprise remaining (e.g., unremoved) portions of the dielectric spacer material 176 (FIG. 1F) on an outer side surface (e.g., an outer sidewall) of the channel material 134 of respective ones of the cell pillar structures 124. The second spacer structures 180 may be located within horizontal areas of the slot regions 115 of the microelectronic device structure 100, may comprise additional remaining (e.g., additional unremoved) portions of the dielectric spacer material 176 (FIG. 1F) on outer side surfaces (e.g., outer sidewalls) of the fourth dielectric liner material 146 of the respective ones of the slot structures 139.

The first spacer structures 178 may respectively be horizontally interposed between the channel material 134 of respective ones of the cell pillar structures 124 and each of the capping material 120, the insulative liner material 118 (if any), and the isolation material 116 of the additional stack structure 112. An individual first spacer structure 178 associated with (e.g., within a horizontal area of) an individual cell pillar structure 124 may have an inner horizontal boundary defined by an outer side surface (e.g., an outer sidewall) of the channel material 134 of the cell pillar structure 124; an outer horizontal boundary defined by surfaces of the capping material 120, the insulative liner material 118 (if any), and the isolation material 116 of the additional stack structure 112; an upper boundary (e.g., an upper surface, an upper end, a top) vertically at (e.g., substantially coplanar with) or proximate (e.g., vertically offset from but close to) an exposed upper surface of the channel material 134 of the cell pillar structure 124; and a lower boundary (e.g., a lower surface, a lower end, a bottom) defined by each of the upper surface 166 of the charge-blocking material 126, the upper surface 156 of the charge-trapping material 128, and the upper surface 168 of the BE dielectric material 130 of the cell pillar structure 124. The lower boundary of an individual first spacer structure 178 may have a non-planar shape complementary to a non-planar topography defined by surfaces of the charge-blocking material 126, the charge-trapping material 128, and the BE dielectric material 130 of the cell pillar structure 124 adjacent thereto. The lower boundary of an individual first spacer structure 178 may be located at or below an upper boundary (e.g., an upper surface) of the isolation material 116. In some embodiments, the lower boundary of an individual first spacer structure 178 is within a vertical span of the isolation material 116 of the additional stack structure 112.

The second spacer structures 180 may respectively including an upper portion within a vertical span of the additional stack structure 112, and a lower portion continuous with the upper portion and at least partially within vertical span of the stack structure 102 (e.g., within a vertical span of the first tier 108A of the stack structure 102). The upper portion of an individual second spacer structure 180 associated with an individual slot structure 139 may be horizontally interposed between the fourth dielectric liner material 146 of the slot structures 139 and each of the capping material 120, the insulative liner material 118 (if any), and the isolation material 116 of the additional stack structure 112. The lower portion of the second spacer structure 180 may be horizontally interposed between the fourth dielectric liner material 146 and the second dielectric liner material 142 of the slot structure 139. An individual second spacer structure 180 associated with an individual slot structure 139 may have an inner horizontal boundary defined by an outer side surface (e.g., an outer sidewall) of the fourth dielectric liner material 146 of the slot structure 139; an outer horizontal boundary defined by surfaces of the capping material 120, the insulative liner material 118 (if any), and the isolation material 116 of the additional stack structure 112, as well as surfaces of the second dielectric liner material 142 of the slot structure 139; an upper boundary (e.g., an upper surface, an upper end, a top) vertically at (e.g., substantially coplanar with) or proximate (e.g., vertically offset from but close to) an upper boundary (e.g., an upper surface, an upper end, a top) of the fourth dielectric liner material 146 of the slot structure 139; and a lower boundary (e.g., a lower end, a bottom) defined by the upper surface 172 of the third dielectric liner material 144 of the slot structure 139. The lower boundary of an individual second spacer structure 180 may be located at or below an upper boundary (e.g., an upper surface) of the first insulative material 106A of the first tier 108A of the stack structure 102. In some embodiments, the lower boundary of an individual second spacer structure 180 is within a vertical span of the first conductive material 104A of the first tier 108A of the stack structure 102.

Referring next to FIG. 1H, illustrated is simplified, partial vertical cross-sectional view of the microelectronic device structure 100 at a processing stage of the method of forming a microelectronic device following the processing stage previously described with reference to FIG. 1G. As shown in FIG. 1H, portions (e.g., upper portions) of the channel material 134 of respective ones of the cell pillar structures 124 may be selectively removed (e.g., selectively etched away, such as selectively wet etched away) through a sixth material removal process. The sixth material removal process may expose (e.g., uncover) portions of the fill material 136 of the respective ones of the cell pillar structures 124. The third material removal process may remove the portions (e.g., upper portions) of the channel material 134 of the respective ones of the cell pillar structures 124 without substantially removing the fill material 136 of the respective ones of the cell pillar structures 124, the first spacer structures 178, the second spacer structures 180, and the fourth dielectric liner material 146 of the slot structures 139. In some embodiments wherein the channel material 134 of respective ones of the cell pillar structures 124 and the capping material 120 of the additional stack structure 112 have different etch selectivities than one another (e.g., are etched at different rates than one another during mutual exposure to an etchant), the third material removal process also does not substantially remove the capping material 120 of the additional stack structure 112. In additional embodiments wherein the channel material 134 of respective ones of the cell pillar structures 124 and the capping material 120 of the additional stack structure 112 have similar etch selectivities to one another (e.g., are etched at substantially the same rate as one another during mutual exposure to an etchant), the third material removal process partially remove (e.g., vertically thin) the capping material 120 of the additional stack structure 112. However, portions (e.g., lower portions) of the capping material 120 may remain following the third material removal. In some embodiments, the sixth material removal process is a wet etching process employing TMAH as an etchant. Following the third material removal process, the exposed portions of the fill material 136 of the respective ones of the cell pillar structures 124 may vertically overlie (e.g., in the Z-direction) the isolation material 116 of the additional stack structure 112.

The sixth material removal process may form openings 182 respectively horizontally interposed between the fill material 136 and BE dielectric material 130 of respective ones of the cell pillar structures 124. An individual opening 182 associated with (e.g., within a horizontal area of) an individual cell pillar structure 124 may have an inner horizontal boundary defined by an outer side surface (e.g., an outer sidewall) of the fill material 136 of the cell pillar structure 124; an outer horizontal boundary defined by an inner side surface (e.g., an inner sidewall) of the BE dielectric material 130 of the cell pillar structure 124; an upper boundary (e.g., an upper end, a top) defined by an upper surface of the first spacer structure 178 horizontally neighboring the cell pillar structure 124; and a lower boundary (e.g., a lower end, a bottom) defined by an upper surface 184 of the channel material 134 of the cell pillar structure 124. The lower boundary of an individual opening 182 (and, hence, the upper surface 184 of the channel material 134) may be located above an upper boundary (e.g., an upper surface) of isolation material 116 of the additional stack structure 112.

Referring next to FIG. 1I, illustrated is simplified, partial vertical cross-sectional view of the microelectronic device structure 100 at a processing stage of the method of forming a microelectronic device following the processing stage previously described with reference to FIG. 1H. As shown in FIG. 1I, portions (e.g., upper portions) of the fill material 136 of respective ones of the cell pillar structures 124 may be selectively removed (e.g., selectively etched away, such as selectively wet etched away) through a seventh material removal process. The seventh material removal process may vertically recess the fill material 136 of the respective ones of the cell pillar structures 124 to expose a portion (e.g., an upper portion) of an inner side surface (e.g., an inner sidewall) of the channel material 134 of the respective ones of the cell pillar structures 124. The seventh material removal process may remove the portions (e.g., upper portions) of the fill material 136 of the respective ones of the cell pillar structures 124 without substantially removing the channel material 134 of the respective ones of the cell pillar structures 124, the capping material 120 of the additional stack structure 112, the first spacer structures 178, the second spacer structures 180, and the fourth dielectric liner material 146 of the slot structures 139. In some embodiments, the seventh material removal process is a wet etching process employing one or more of BOE and DHF etchant. Following the seventh material removal process, the exposed portion (e.g., exposed upper portion) of the inner side surface of the channel material 134 of an individual cell pillar structure 124 may vertically overlie a lower boundary of the first tier 108A of the stack structure 102. In some embodiments, following the seventh material removal process, the exposed portion of the inner side surface of the channel material 134 of an individual cell pillar structure 124 vertically overlies a lower boundary of the first insulative material 106A of the first tier 108A of the stack structure 102.

The seventh material removal process may expand (e.g., horizontally expand, vertically expand) the openings 182 (FIG. 1H) to form additional openings 186. An individual additional opening 186 associated with (e.g., within a horizontal area of) an individual cell pillar structure 124 may have an outer horizontal boundary defined an inner side surface (e.g., an inner sidewall) of the first spacer structure 178 horizontally neighboring the cell pillar structure 124 and surfaces (e.g., the upper surface 184, an upper portion of the inner side surface) of the channel material 134 of the cell pillar structure 124; an upper boundary (e.g., an upper end, a top) defined by an upper surface of the first spacer structure 178 horizontally neighboring the cell pillar structure 124; and a lower boundary (e.g., a lower end, a bottom) defined by an upper surface 188 of the fill material 136 of the cell pillar structure 124. The lower boundary of an individual additional opening 186 (and, hence, the upper surface 188 of the fill material 136) may be vertically located at or below a lower boundary (e.g., a lower surface) of the isolation material 116 of the additional stack structure 112. In some embodiments, the lower boundary of an individual additional opening 186 is within a vertical span of the first tier 108A of the stack structure 102, such as within a vertical extent of the first insulative material 106A of the first tier 108A of the stack structure 102, or within a vertical extent of the first conductive material 104A of the first tier 108A of the stack structure 102.

Referring next to FIG. 1J, illustrated is simplified, partial vertical cross-sectional view of the microelectronic device structure 100 at a processing stage of the method of forming a microelectronic device following the processing stage previously described with reference to FIG. 1I. As shown in FIG. 1I, a source material 190 may be formed (e.g., deposited, such as conformally deposited) on or over exposed surfaces of the cell pillar structures 124, the slot structures 139, and the additional stack structure 112. The source material 190 may substantially continuously extend across the block regions 114 and the slot regions 115 of the microelectronic device structure 100. The source material 190 may at least partially (e.g., substantially) conform to a topography defined by the surfaces upon which the source material 190 is formed. In addition, the source material 190 may substantially fill the additional openings 186 (FIG. 1I). The source material 190 may contact (e.g., physically contact, electrically contact) and substantially cover upper portions (e.g., the upper surface 184, an upper portion of the inner side surface) of the channel material 134 of respective ones of the cell pillar structures 124 exposed following the seventh material removal process previously described with reference to FIG. 1I. The source material 190 may also contact and substantially cover surfaces of each of the fill material 136 (e.g., the upper surface 188) of respective ones of the cell pillar structures 124, the first spacer structures 178, the second spacer structures 180, the fourth dielectric liner material 146 of respective ones of the slot structures 139, and the capping material 120 of the additional stack structure 112 exposed following the seventh material removal process previously described with reference to FIG. 1I.

The source material 190 may be formed of and include at least one doped semiconductor material. For example, the source material 190 may be formed of and include semiconductor material doped (e.g., impregnated) with one or more conductivity enhancing species (e.g., one or more N-type dopants, one or more P-type dopants). In some embodiments, the source material 190 is formed of and includes polycrystalline silicon (also referred to herein as “polysilicon”) doped (e.g., relatively highly doped) with at least one N-type dopant (e.g., one or more of phosphorus, arsenic, antimony, and bismuth). For example, the source material 190 may be formed of and include N+ polysilicon. In additional embodiments, the source material 190 is formed of and includes polycrystalline silicon doped (e.g., relatively highly doped) with at least one P-type dopant (e.g., one or more of boron, aluminum, and gallium).

The source material 190 may be substantially homogeneous, or the source material 190 may be heterogeneous. In some embodiments, the source material 190 is substantially homogeneous. For example, the source material 190 may be formed of and include only one (1) doped semiconductor material (e.g., only N+ polysilicon), and a concentration of dopant(s) (e.g., N-type dopant(s), such as one or more of phosphorus, arsenic, antimony, and bismuth) may be substantially uniform through-out dimensions (e.g., vertical dimensions, horizontal dimensions) of the doped semiconductor material (and, hence, the source material 190). In additional embodiments, the source material 190 is substantially heterogeneous. For example, the source material 190 may include multiple (e.g., more than one) doped semiconductor materials and/or doped semiconductor material in combination with undoped semiconductor material. In some embodiments, the source material 190 includes a P-type semiconductor material (e.g., P-type polysilicon) and an N-type semiconductor material (e.g., N-type polysilicon, such as N+ polysilicon) on or over the P-type semiconductor material. In additional embodiments, the source material 190 includes a first N-type semiconductor material (e.g., N-type polysilicon having a first N-type dopant concentration), and a second N-type semiconductor material (e.g., additional N-type polysilicon having a second, different N-type dopant concentration) on or over the first N-type semiconductor material.

Optionally, an initially formed source material (including at least one initial, doped semiconductor material) may be annealed (e.g., laser annealed, thermally annealed) to form the source material 190. Annealing the initially formed source material may, for example, enhance dopant activation within the source material 190 and/or may enhance desirable surface characteristics (e.g., surface smoothness) for the source material 190. In some embodiments, an initially formed source material is laser annealed using a laser power less than or equal to about 0.4 joules per square centimeter (J/cm²). Such a laser power may be sufficient to activate dopant(s) (e.g., phosphorus) of the source material 190 without imparting relatively high temperatures that may otherwise adversely impact other features (e.g., the first conductive material 104A of the first tier 108A of the stack structure 102) of the microelectronic device structure 100. The laser power employed by the laser annealing process may not be high enough (e.g., greater than or equal to about 0.8 J/cm²) to substantially diffuse dopant(s) (e.g., phosphorus) of the initially formed initially formed source material into the channel material 134 of respective ones of the cell pillar structures 124.

The source material 190 may be employed to form a source structure 192 of the microelectronic device structure 100. The source structure 192 may be coupled to the channel material 134 of respective ones of the cell pillar structures 124. Accordingly, the source structure 192 may be coupled to the vertical extending strings of memory cells 138 within the block regions 114 of the microelectronic device structure 100.

The formation of the source structure 192 may facilitate the formation of a microelectronic device 194 including the microelectronic device structure 100. The microelectronic device 194 is configured for source-side GIDL-assisted erase operations on the vertically extending strings of memory cells 138. The microelectronic device 194 further includes additional features (e.g., control logic circuitry, back-end-of-line (BEOL) structures), which are not described in detail herein. For example, the microelectronic device 194 may include control logic circuitry vertically below (e.g., in the Z-direction) the stack structure 102 and operatively associated with the vertically extending strings of memory cells 138. In some embodiments, the control logic circuitry is at least partially positioned within a horizontal area of an array of the vertically extending strings of memory cells 138, such that the microelectronic device 194 has a so-called CMOS under array (“CuA”) configuration. In some embodiments, the control logic circuitry formed in a peripheral circuitry structure (e.g., a peripheral circuitry wafer) formed separately from a memory array structure (e.g., a memory array wafer) including the vertically extending strings of memory cells 138, and then the peripheral circuitry structure and the memory array structure are bonded (e.g., through so-called “wafer-to-wafer” (W2W) bonding) through one or more of dielectric-to-dielectric bonding and metal-to-metal bonding. Such bonding (e.g., W2W bonding) may be performed before or after the formation of the source structure 192. In some embodiments, such bonding (e.g., W2W bonding) is performed prior to the processing described herein with reference to FIGS. 1A through 1J.

Formation of the source structure 192 including the source material 190 in physical contact with channel material 134 of respective ones of the cell pillar structures 124 may provide the microelectronic device 194 improved performance relative to conventional device configurations. In particular, the microelectronic device structure 100 following the processing described with reference to FIG. 1J may facilitate enhanced electric field coupling between the source structure 192 and the channel material 134 of respective ones of the cell pillar structures 124, thereby increasing source-side GIDL current. Increased source-side GIDL current facilitates relatively more effective body biasing of the cell pillar structures 124, enabling improved control of channel potential during various memory operations. As a result, relative to conventional device configurations, the microelectronic device 194 may have reduced disturbances during read operations and program operations, improved data retention characteristics, and/or enhanced overall memory cell 138 reliability. The structures and methods of the disclosure are advantageous for the formation of advanced 3D memory devices (e.g., 3D NAND Flash memory devices), including those formed through W2W bonding techniques, where increased physical separation between a source structure and SGS devices may otherwise diminish GIDL performance.

Thus, a microelectronic device according to embodiments of the disclosure includes a stack structure, a cell pillar structure, a dielectric spacer structure, and a source structure. The stack structure includes tiers vertically stacked relative to one another and respectively including conductive material and insulative material vertically neighboring the conductive material. The cell pillar structure vertically extends through the stack structure and includes a fill material, a channel material outwardly horizontally surrounding the fill material, and an outer material stack outwardly horizontally surrounding the channel material. The dielectric spacer structure is vertically above the stack structure and in physical contact with an upper portion of an outer side surface of the channel material of the cell pillar structure. The source structure includes doped semiconductor material covering the dielectric spacer structure and physically contacting an upper portion of an inner side surface of the channel material of the cell pillar structure.

Furthermore, in accordance with embodiments of the disclosure, a method of forming a microelectronic device includes forming a microelectronic device structure including a stack structure, an additional stack structure, and a cell pillar structure. The stack structure includes tiers vertically stacked relative to one another and respectively including conductive material and insulative material vertically neighboring the conductive material. The additional stack structure is vertically above the stack structure and includes an isolation material and a capping material over the isolation material. The cell pillar structure vertically extends through the stack structure and into the additional stack structure. The cell pillar structure includes a fill material, a channel material outwardly surrounding the fill material, and an outer material stack outwardly surrounding the channel material. An upper portion of the outer material stack of the cell pillar structure within a vertical span of the additional stack structure is removed to expose an upper portion of the channel material of the cell pillar structure. A dielectric spacer structure is formed on an outer side surface of the upper portion of the channel material of the cell pillar structure. Portions of the channel material and the fill material of the cell pillar structure are removed to expose an upper portion of an inner side surface of the channel material of the cell pillar structure. A source structure is formed and includes doped semiconductor material covering the dielectric spacer structure and in physical contact with the upper portion of the inner side surface of the channel material of the cell pillar structure.

Moreover, a memory device according to embodiments of the disclosure includes a stack structure, a pillar structure, an insulative spacer structure, and a source structure. The stack structure includes a vertically alternating sequence of conductive material and insulative material. The pillar structure includes semiconductor material vertically extending completely through the stack structure. The semiconductor material has a top surface vertically above the stack structure. The insulative spacer structure is vertically above the stack structure and is in physical contact with an outer sidewall of the semiconductor material of the pillar structure. An upper surface of the insulative spacer structure is vertically above the top surface of the semiconductor material of the pillar structure. The source structure includes doped semiconductor material on: each of an inner sidewall and the top surface of the semiconductor material of the pillar structure; and each of an inner side surface, an outer side surface, and the upper surface of the insulative spacer structure.

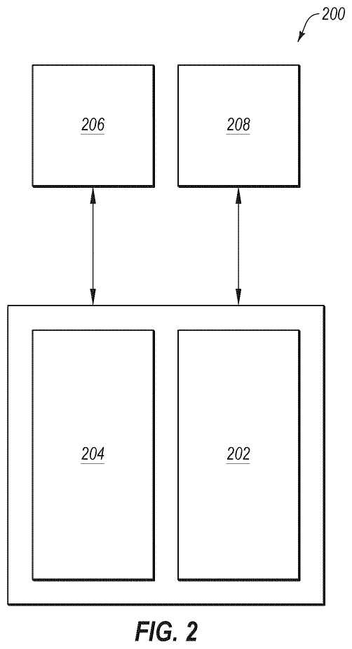

Microelectronic devices (e.g., the microelectronic device 194 (FIG. 1J)) in accordance with embodiments of the disclosure may be used in embodiments of electronic systems of the disclosure. For example, FIG. 2 is a block diagram of an illustrative electronic system 200 according to embodiments of disclosure. The electronic system 200 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 200 includes at least one memory device 202. The memory device 202 may comprise, for example, a microelectronic device (e.g., the microelectronic device 194 (FIG. 1J)) previously described herein. The electronic system 200 may further include at least one electronic signal processor device 204 (often referred to as a “microprocessor”). The electronic signal processor device 204 may, optionally, include a microelectronic device (e.g., microelectronic device 194 (FIG. 1J)) previously described herein. While the memory device 202 and the electronic signal processor device 204 are depicted as two (2) separate devices in FIG. 2, in additional embodiments, a single (e.g., only one) memory/processor device having the functionalities of the memory device 202 and the electronic signal processor device 204 is included in the electronic system 200. In such embodiments, the memory/processor device may include a microelectronic device (e.g., microelectronic device 194 (FIG. 1J)) previously described herein. The electronic system 200 may further include one or more input devices 206 for inputting information into the electronic system 200 by a user, such as, for example, a mouse or other pointing device, a keyboard, a touchpad, a button, or a control panel. The electronic system 200 may further include one or more output devices 208 for outputting information (e.g., visual or audio output) to a user such as, for example, a monitor, a display, a printer, an audio output jack, a speaker, etc. In some embodiments, the input device 206 and the output device 208 comprise a single touchscreen device that can be used both to input information to the electronic system 200 and to output visual information to a user. The input device 206 and the output device 208 may communicate electrically with one or more of the memory device 202 and the electronic signal processor device 204.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device, comprising:
a stack structure comprising tiers vertically stacked relative to one another and respectively comprising conductive material and insulative material vertically neighboring the conductive material;
a cell pillar structure vertically extending through the stack structure and comprising:
a fill material;
a channel material outwardly horizontally surrounding the fill material; and
an outer material stack outwardly horizontally surrounding the channel material;
a dielectric spacer structure vertically above the stack structure and in physical contact with an upper portion of an outer side surface of the channel material of the cell pillar structure; and
a source structure comprising doped semiconductor material covering the dielectric spacer structure and physically contacting an upper portion of an inner side surface of the channel material of the cell pillar structure.

2. The microelectronic device of claim 1, wherein the doped semiconductor material of the source structure also physically contacts each of:
an upper surface of the channel material of the cell pillar structure; and
an inner sidewall of the dielectric spacer structure.

3. The microelectronic device of claim 1, wherein a portion of the doped semiconductor material of the source structure vertically extends into and vertically terminates within a vertical span of an uppermost one of the tiers of the stack structure.

4. The microelectronic device of claim 3, wherein an additional portion of the doped semiconductor material of the source structure physically contacts an outer sidewall of the dielectric spacer structure and vertically terminates above the stack structure.

5. The microelectronic device of claim 1, further comprising:
an insulative isolation material vertically interposed between the stack structure and the source structure; and
a semiconductive capping material vertically interposed between the insulative isolation material and the source structure, the semiconductive capping material in physical contact with each of the dielectric spacer structure and the doped semiconductor material of the source structure.

6. The microelectronic device of claim 5, wherein the channel material of the cell pillar structure vertically extends completely through each of the insulative isolation material and the semiconductive capping material.

7. The microelectronic device of claim 6, wherein an upper boundary of the outer material stack of the cell pillar structure is vertically below an upper surface of the insulative isolation material.

8. The microelectronic device of claim 1, wherein the doped semiconductor material of the source structure comprises N-type doped polycrystalline silicon.

9. The microelectronic device of claim 8, wherein the dielectric spacer structure comprises dielectric nitride material.

10. The microelectronic device of claim 1, further comprising a slot structure horizontally offset from the cell pillar structure and vertically extending through the stack structure, the slot structure comprising:
an additional fill material;
a dielectric liner material outwardly horizontally surrounding the additional fill material; and
at least one additional liner material outwardly horizontally surrounding the dielectric liner material.

11. The microelectronic device of claim 10, further comprising an additional dielectric spacer structure vertically above the stack structure and in physical contact with an upper portion of an outer side surface of the slot structure, the additional dielectric spacer structure and the dielectric spacer structure having substantially a same material composition as one another.

12. A method of forming a microelectronic device, comprising:
forming a microelectronic device structure comprising:
a stack structure comprising tiers vertically stacked relative to one another and respectively including conductive material and insulative material vertically neighboring the conductive material;
an additional stack structure vertically above the stack structure and comprising an isolation material and a capping material over the isolation material; and
a cell pillar structure vertically extending through the stack structure and into the additional stack structure, the cell pillar structure comprising a fill material, a channel material outwardly surrounding the fill material, and an outer material stack outwardly surrounding the channel material;
removing an upper portion of the outer material stack of the cell pillar structure within a vertical span of the additional stack structure to expose an upper portion of the channel material of the cell pillar structure;
forming a dielectric spacer structure on an outer side surface of the upper portion of the channel material of the cell pillar structure;
removing portions of the channel material and the fill material of the cell pillar structure to expose an upper portion of an inner side surface of the channel material of the cell pillar structure; and
forming a source structure comprising doped semiconductor material covering the dielectric spacer structure and in physical contact with the upper portion of the inner side surface of the channel material of the cell pillar structure.

13. The method of claim 12, wherein removing an upper portion of the outer material stack of the cell pillar structure within a vertical span of the additional stack structure comprises forming a remaining portion of the outer material stack of the cell pillar structure to have an upper boundary below an upper surface of the isolation material of the additional stack structure.

14. The method of claim 13, wherein forming a dielectric spacer structure on an outer side surface of the upper portion of the channel material of the cell pillar structure comprises:
forming a dielectric spacer material on and substantially continuously extending across exposed surfaces of each of the channel material of the cell pillar structure, the outer material stack of the cell pillar structure, the isolation material of the additional stack structure, and the capping material of the additional stack structure; and
removing portions of the dielectric spacer material on upper surfaces of the channel material of the cell pillar structure and the capping material of the additional stack structure.

15. The method of claim 14, further comprising selecting the dielectric spacer material to comprise dielectric nitride material.

16. The method of claim 12, wherein removing portions of the channel material and the fill material of the cell pillar structure comprises:
after forming the dielectric spacer structure, vertically recessing the channel material of the cell pillar structure to expose a portion of the fill material of the cell pillar structure; and
after vertically recessing the channel material of the cell pillar structure, vertically recessing the fill material of the cell pillar structure.

17. The method of claim 16, wherein vertically recessing the channel material of the cell pillar structure comprises forming an upper surface of a remaining portion of the channel material to vertically overlie an upper boundary of the stack structure.

18. The method of claim 17, wherein vertically recessing the fill material of the cell pillar structure comprises forming a top surface of a maintained portion of the fill material to vertically underlie the upper boundary of the stack structure.

19. The method of claim 12, wherein forming a source structure comprises forming the doped semiconductor material thereof to further physically contact each of an upper surface of a remaining portion of the fill material of the cell pillar structure, an inner sidewall of the dielectric spacer structure, a top surface of the dielectric spacer structure, an outer sidewall of the dielectric spacer structure, and an upper surface of the capping material of the additional stack structure.

20. A memory device, comprising:
a stack structure comprising a vertically alternating sequence of conductive material and insulative material;
a pillar structure comprising semiconductor material vertically extending completely through the stack structure, the semiconductor material having a top surface vertically above the stack structure;
an insulative spacer structure vertically above the stack structure and in physical contact with an outer sidewall of the semiconductor material of the pillar structure, an upper surface of the insulative spacer structure vertically above the top surface of the semiconductor material of the pillar structure; and
a source structure comprising doped semiconductor material on:
each of an inner sidewall and the top surface of the semiconductor material of the pillar structure; and
each of an inner side surface, an outer side surface, and the upper surface of the insulative spacer structure.
